(19) United States
(12) Patent Application Publication
(10) Pub. No.: US 2009/0213946 A1
(43) Pub. Date: Aug. 27, 2009

(54) PARTIAL RECONFIGURATION FOR A MIMO-OFDM COMMUNICATION SYSTEM

(75) Inventors: Christopher H. Dick, San Jose, CA (US); Raghavendar M. Rao, Austin, TX (US)

Correspondence Address: XILINX, INC;ATTN: LEGAL DEPARTMENT, 2100 LOGIC DR, SAN JOSE, CA, 95124, US

(73) Assignee: XILINX, INC., San Jose, CA (US)

(21) Appl. No.: 12/036,940

(22) Filed: Feb. 25, 2008

(51) Int. Cl. H04K 1/10; H03K 19/003

(52) U.S. Cl. 375/260; 326/9

(57) ABSTRACT

Partial reconfiguration of programmable logic for supporting a Multiple-input, Multiple-Output Orthogonal Frequency Division Multiplexing (“MIMO-OFDM”) communication system is described. A PHY block in a programmable device may be instantiated generally in part in programmable logic of the programmable device. Control information is obtained for a network node when deployed and/or from a wireless transmission of a packet or frame, which is demodulated in the PHY block. Responsive to the control information demodulated, bitstream information is obtained to configure the portion of the PHY block using the programmable logic of the programmable device.

### FIELD OF THE INVENTION

One or more aspects of the invention relate generally to integrated circuits and, more particularly, to partial reconfiguration of programmable logic for supporting a Multiple-input, Multiple-Output Orthogonal Frequency Division Multiplexing (“MIMO-OFDM”) communication system.

### BACKGROUND OF THE INVENTION

Programmable logic devices (“PLDs”) are a well-known type of integrated circuit that can be programmed to perform specified logic functions. One type of PLD, the field programmable gate array (“FPGA”), typically includes an array of programmable tiles. These programmable tiles can include, for example, input/output blocks (“IOBs”), configurable logic blocks (“CLBs”), dedicated random access memory blocks (“BRAMs”), multipliers, digital signal processing blocks (“DSPs”), processors, clock managers, delay lock loops (“DLLs”), and so forth. As used herein, “include” and “including” mean including without limitation.

One such FPGA is the Xilinx Virtex™ FPGA available from Xilinx, Inc., 2100 Logic Drive, San Jose, Calif. 95124. Another type of PLD is the Complex Programmable Logic Device (“CPLD”). A CPLD includes two or more “function blocks” connected together and to input/output (“I/O”) resources by an interconnect switch matrix. Each function block of the CPLD includes a two-level AND/OR structure similar to those used in Programmable Logic Arrays (“PLAs”) and Programmable Array Logic (“PAL”) devices. Other PLDs are programmed by applying a processing layer, such as a metal layer, that programmably interconnects the various elements on the device. These PLDs are known as mask programmable devices. PLDs can also be implemented in other ways, for example, using fuse or antifuse technology. The terms “PLD” and “programmable logic device” include but are not limited to these exemplary devices, as well as encompassing devices that are only partially programmable.

For purposes of clarity, FPGAs are described below though other types of PLDs may be used. FPGAs may include one or more embedded microprocessors. For example, a microprocessor may be located in an area reserved for it, generally referred to as a “processor block.”

Multiple-input, multiple-output orthogonal frequency division multiplexing (“MIMO-OFDM”) systems are gaining popularity. For example, MIMO-OFDM systems are making their way into more recent wireless communication standards such as IEEE 802.11n, 802.16, 802.16e, and 3GPP-LTE, among other known or proposed standards. Many of these MIMO-OFDM systems involve a variety of Fourier transform sizes, data rates, antenna configurations, and encoding modes. Examples of encoding modes used in MIMO-OFDM systems include Space-Time Block Code (“STBC”) encoding, including interference canceling STBC encoding, and spatial multiplexing, among other known MIMO modulation schemes.

A MIMO-OFDM transceiver includes both a MIMO-OFDM receiver and a MIMO-OFDM transmitter. Each MIMO-OFDM receiver and transmitter may be configured for all associated options and modes for use in a MIMO-OFDM communication system. For example, a WiMax IEEE 802.16e communication system may use STBC or spatial multiplexing modulation and may use a convolutional code, a convolutional Turbo code (“CTC”), a Turbo Product code (“TPC”), or a low density parity check (“LDPC”) code. For example, CTC and LDPC code decoders conventionally are complex modules involving substantial circuitry overhead. Having both Turbo code and LDPC code encoding/decoding programmed into programmable logic conventionally would involve multiple FPGAs to provide both encoding by a transceiver and decoding by a receiver in a transceiver implemented on a circuit board.

However, in some MIMO-OFDM communication systems, not all possible receiver and transmitter capabilities are used simultaneously.

### SUMMARY OF THE INVENTION

Accordingly, it would be desirable and useful to provide a MIMO-OFDM receiver, transmitter, or transceiver which is dynamically configurable in order to support various capabilities for on demand use to lessen circuitry overhead.

One or more aspects generally relate to integrated circuits and, more particularly, to partial reconfiguration of programmable logic for supporting a Multiple-Input, Multiple-Output Orthogonal Frequency Division Multiplexing (“MIMO-OFDM”) communication system.

An aspect is a method for providing a communication system. The method includes: instantiating a physical layer block in a programmable device, where the physical layer block is instantiated at least in part in programmable logic of the programmable device; and obtaining communication information from a first wireless network node of a communication network to configure a portion of the physical layer block of a second wireless network node of the communication network. The portion of the physical layer block is configured using the programmable logic; and the portion of the physical layer block is configured responsive to the communication information. The communication system is part of the second wireless network node. The configuring of the portion of the physical layer block includes: selectively obtaining at least one partial bitstream from a store of partial bitstreams responsive to the communication information, where the communication information is associated with the communication network in which the communication system is capable of being deployed; and loading the at least one partial bitstream into the programmable logic for the configuring of the portion of the physical layer block.

Another aspect is another method for providing a communication system. The other method includes configuring a physical layer block in a programmable device responsive to at least one directive from a microprocessor that is executing a media access control (“MAC”) layer of the communication system. While the microprocessor executes the MAC layer, the configuring includes: obtaining a communication from a wireless transmission from a network node of a communication network, where the communication has control information and receipt of the control information prompts the microprocessor to issue the at least one directive; selecting using the microprocessor at least one partial bitstream from a store of partial bitstreams responsive to the control information obtained; decoding the control information in the physical layer block to output decoded information; sending the decoded information to the MAC layer being executed using the microprocessor; and loading the at least one partial reconfiguration bitstream into the programmable logic for the configuring of at least the portion of the physical layer block responsive to the at least one directive from the microprocessor. The control information is associated with the communication network in which the communication system is capable of being deployed.

Yet another aspect is a communication system. The communication system includes: a physical layer block instantiated in a programmable device, where the first physical layer block is capable of being instantiated in part in programmable logic of the programmable device for dynamic partial reconfiguration of a portion of the physical layer block; and a store of partial bitstreams from which bitstream information is selectively retrievable for the dynamic partial reconfiguration of the portion of the physical layer block. The bitstream information is capable of being selectively retrieved responsive to control information in a transmission for a communication network in which the communication system is capable of being deployed.

### BRIEF DESCRIPTION OF THE DRAWINGS

Accompanying drawing(s) show exemplary embodiment(s) in accordance with one or more aspects of the invention; however, the accompanying drawing(s) should not be taken to limit the invention to the embodiment(s) shown, but are for explanation and understanding only.

FIG. 1 is a simplified block diagram depicting an exemplary embodiment of a columnar Field Programmable Gate Array (“FPGA”) architecture in which one or more aspects of the invention may be implemented.

FIG. 2 is a block diagram depicting an exemplary embodiment of a base station for a wireless communication system.

FIG. 3 is a block diagram depicting an exemplary alternative embodiment of a base station.

FIG. 4 is a block depicting an exemplary embodiment of a channel encoding/modulation (“CEM”) block.

FIG. 5 is a block diagram depicting an exemplary embodiment of a channel demodulation/decoding (“CDD”) block.

FIG. 6 is a block diagram depicting an exemplary embodiment of a wireless communication network.

FIG. 7 is a flow diagram depicting an exemplary embodiment of an FPGA configuration flow.

### DETAILED DESCRIPTION OF THE DRAWINGS

In the following description, numerous specific details are set forth to provide a more thorough description of the specific embodiments of the invention. It should be apparent, however, to one skilled in the art, that the invention may be practiced without all the specific details given below. In other instances, well known features have not been described in detail so as not to obscure the invention. For ease of illustration, the same number labels are used in different diagrams to refer to the same items; however, in alternative embodiments the items may be different. Even though single instances of signals or circuits are illustratively shown, it should be appreciated that multiple instance of either or both signals and circuits may be used as may vary from application to application.

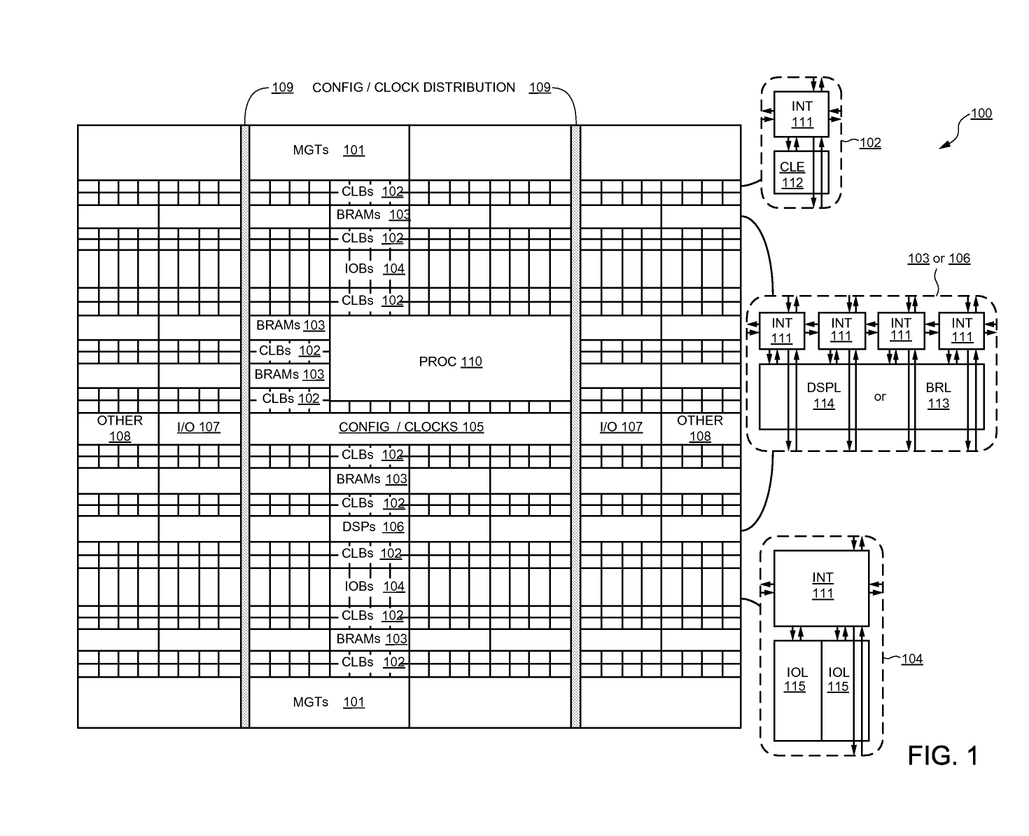

FIG. 1 illustrates an FPGA architecture 100 that includes a large number of different programmable tiles including multi-gigabit transceivers (“MGTs”) 101, configurable logic blocks (“CLBs”) 102, random access memory blocks (“BRAMs”) 103, input/output blocks (“IOBs”) 104, configuration and clocking logic (“CONFIG/CLOCKS”) 105, digital signal processing blocks (“DSPs”) 106, specialized input/output ports (“I/O”) 107 (e.g., configuration ports and clock ports), and other programmable logic 108 such as digital clock managers, analog-to-digital converters, system monitoring logic, and so forth. Some FPGAs also include dedicated processor blocks (“PROC”) 110.

In some FPGAs, each programmable tile includes a programmable interconnect element (“INT”) 111 having standardized connections to and from a corresponding interconnect element 111 in each adjacent tile. Therefore, the programmable interconnect elements 111 taken together implement the programmable interconnect structure for the illustrated FPGA. Each programmable interconnect element 111 also includes the connections to and from any other programmable logic element(s) within the same tile, as shown by the examples included at the right side of FIG. 1.

For example, a CLB 102 can include a configurable logic element (“CLE”) 112 that can be programmed to implement user logic plus a single programmable interconnect element 111. A BRAM 103 can include a BRAM logic element (“BRL”) 113 in addition to one or more programmable interconnect elements 111. Typically, the number of interconnect elements included in a tile depends on the height of the tile. In the pictured embodiment, a BRAM tile has the same height as four CLBs, but other numbers (e.g., five) can also be used. A DSP tile 106 can include a DSP logic element (“DSPL”) 114 in addition to an appropriate number of programmable interconnect elements 111. An IOB 104 can include, for example, two instances of an input/output logic element (“IOL”) 115 in addition to one instance of the programmable interconnect element 111. As will be clear to those of skill in the art, the actual I/O pads connected, for example, to the I/O logic element 115 are manufactured using metal layered above the various illustrated logic blocks, and typically are not confined to the area of the I/O logic element 115.

In the pictured embodiment, a columnar area near the center of the die is used for configuration, I/O, clock, and other control logic. Vertical areas 109 extending from this column are used to distribute the clocks and configuration signals across the breadth of the FPGA.

Some FPGAs utilizing the architecture illustrated in FIG. 1 include additional logic blocks that disrupt the regular columnar structure making up a large part of the FPGA. The additional logic blocks can be programmable blocks and/or dedicated logic. For example, the processor block 110 shown in FIG. 1 spans several columns of CLBs and BRAMs.

Note that FIG. 1 is intended to illustrate only an exemplary FPGA architecture. The numbers of logic blocks in a column, the relative widths of the columns, the number and order of columns, the types of logic blocks included in the columns, the relative sizes of the logic blocks, and the interconnect/logic implementations included at the right side of FIG. 1 are purely exemplary. For example, in an actual FPGA more than one adjacent column of CLBs is typically included wherever the CLBs appear, to facilitate the efficient implementation of user logic. FPGA 100 illustratively represents a columnar architecture, though FPGAs of other architectures, such as ring architectures for example, may be used. FPGA 100 may be a Virtex-4 or Virtex-5 FPGA from Xilinx, Inc. of San Jose, Calif.

It should be appreciated that FPGAs are growing in popularity for implementing communication systems, in particular for implementing infrastructure wireless communication systems. For example, FPGAs are very popular for implementing wireless communication systems based on IEEE specifications 802.16, and 802.16e, 3GPP, and 3GPP-LTE wireless communication systems, among others. This increase in popularity is due at least in part to FPGAs having DSPs 106, as well as embedded memory such as BRAMs 103, that may be configured as first-in, first-out buffers (“FIFOs”). Although examples described herein are presented using embodiments having an FPGA, in general any programmable device, such as an integrated circuit that is partially programmable or has programmable resources such as programmable fabric or one or more processors may be used with the techniques and structures disclosed.

As indicated above, some MIMO-OFDM communication systems, such as time division duplexed (TDD) systems, have transceivers which do not simultaneously use transmit and receive functions. Moreover, when a packet of data (“packet”) or a frame of data is demodulated and decoded, the receiver may only use a subset of all the options and modes supported in such a MIMO-OFDM communication system. The following description is in terms of packet-based communication. However, from the following description of packet-based communication, frame-based communication, or other form of packaged data communication, shall be understood by one of ordinary skill in the art.

One or more modules related to each mode of operation, such as for demodulating and decoding of a packet, may be provided. These one or more modules may be loaded or otherwise dynamically instantiated on demand in programmable logic using partial reconfiguration. By using partial reconfiguration of programmable logic, one or more design modules may be swapped with one or more other modules instantiated in programmable logic. This swapping may be done dynamically or “on-the-fly,” which facilitates operating a remainder of a design while one or more subsystems or subsets of a design are effectively being redefined. The remainder of the design, or a significant portion thereof, may continue to operate during partial reconfiguration. Accordingly, programmable logic resources may be allocated for partial reconfiguration, and these programmable logic resources may be shared among different sets of one or more design modules. These different sets of one or more design modules may be stored as respective partial bitstreams. Delivery of one or more partial bitstreams to program programmable logic may be via a JTAG interface, a SelectMAP interface, a serial configuration interface, ICAP configuration interface, or other data interface. As partial reconfiguration is known, it is not described in unnecessary detail herein.

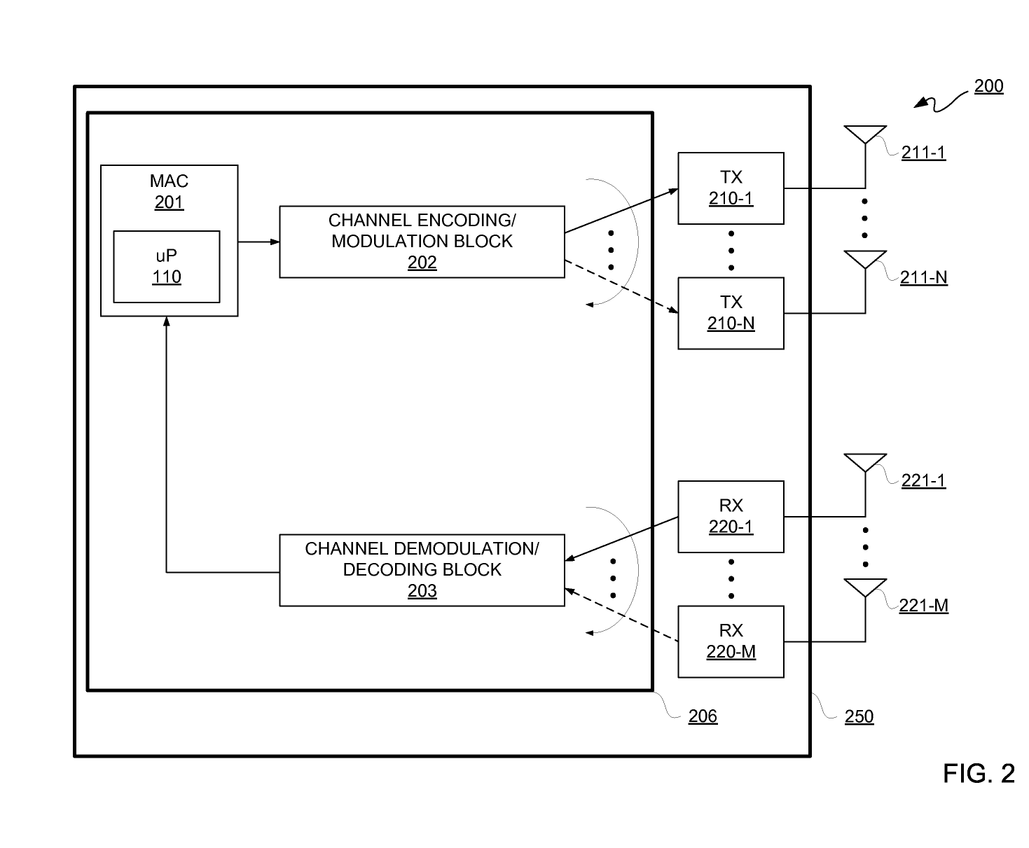

FIG. 2 is a block diagram depicting an exemplary embodiment of a base station 200 for a wireless network. Base station 200 includes one or more transmitters (“TX”) 210-1 through 210-N, for N a positive integer greater than one. Transmitters 210-1 through 210-N may be respectively coupled to antennas 211-1 through 211-N. Transmitters 210-1 through 210-N are coupled to antennas 211-1 through 211-N to transmit modulated/encoded packets obtained from channel encoding/modulation (“CEM”) block 202.

CEM block 202 may be for communicating packets via transmitters 210-1 through 210-N on one or more channels or sub-channels. CEM block 202 may be coupled to receive control signaling and data to be transmitted from media access control (“MAC”) 201. MAC 201 may be operated using software, as is known, which may be run on an embedded microprocessor 110. Base station 200 may include receivers (“RX”) 220-1 through 220-M, for M a positive integer greater than one. Receivers 220-1 through 220-M may be respectively coupled to antennas 221-1 through 221-M of base station 200.

The number of transmitters 210-1 through 210-N need not equal the number of receivers 220-1 through 220-M. Furthermore, while a base station need not have an array of transmitters or an array of receivers, or a combination thereof, benefits associated with MIMO-OFDM may be achieved by using arrays of transmitters or arrays of receivers, or a combination thereof. Communications received by antennas 221-1 through 221-M and respectively provided to receivers 220-1 through 220-M may be provided to channel demodulation/decoding (“CDD”) block 203. MAC 201 of base station 200 may be coupled to receive data received by receivers 220-1 through 220-M, namely “received data,” which has been demodulated and decoded from CDD block 203.

Packets obtained from such communication may contain data which may be provided to MAC 201. Furthermore, a single programmable device 206, such as an FPGA, may be used for blocks 202 and 203, as well as MAC 201. For instance, use of embedded microprocessor 110 for operation of MAC 201 and partial reconfiguration of blocks 202 and 203 facilitates having sufficient programmable logic resources for implementation. Programmable device 206 may be FPGA 100 of FIG. 1. A circuit board 250 may be used for coupling programmable device 206 to transmitters 210-1 through 210-N and receivers 220-1 through 220-M. Though not shown in the embodiment illustratively shown in FIG. 2 for purposes of clarity and not limitation, all or portions of transmitters 210-1 through 210-N or of receivers 220-1 through 220-M, or a combination thereof, may optionally be implemented in programmable device 206.

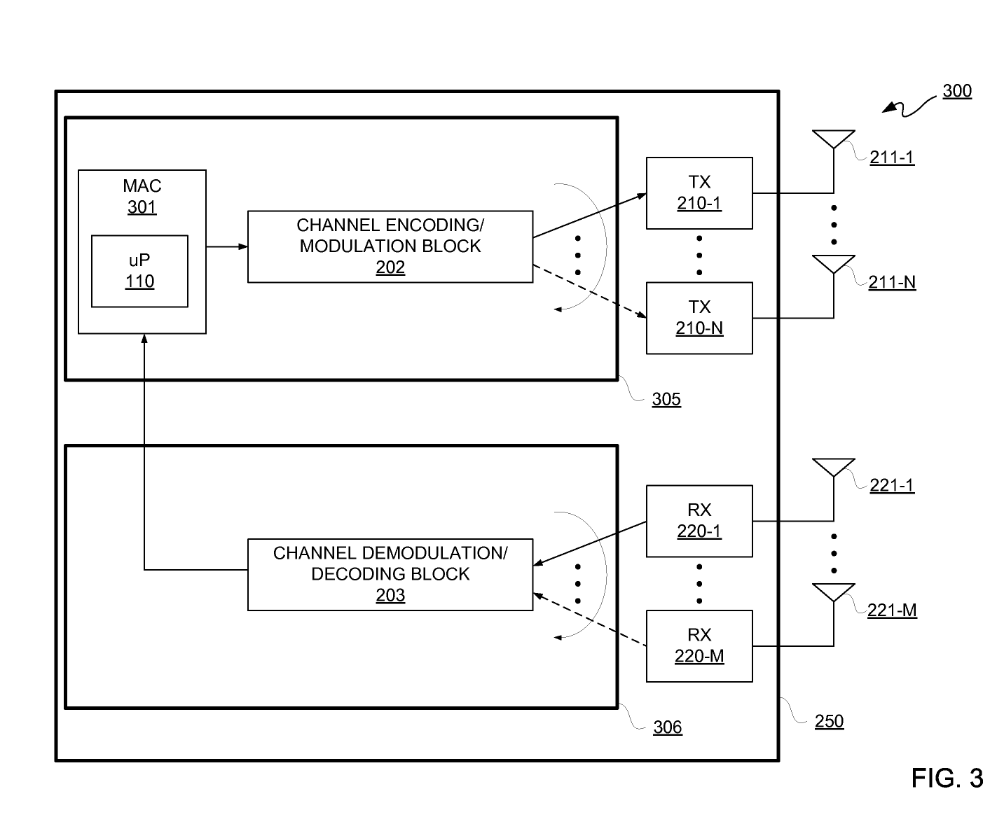

FIG. 3 is a block diagram depicting an exemplary alternative embodiment of a base station 300. Base station 300 has common components with base station 200 of FIG. 2, and accordingly description of such common components is not repeated for purposes of clarity. Base station 300 includes programmable devices, for instance FPGAs 305 and 306, mounted to circuit board 250. FPGA 305 is associated with a transmit path, and FPGA 306 is associated with a receive path. Separate FPGAs for the transmit and receive paths are used in base station 300 with a shared MACs 301 associated with either FPGAs 305 or 306. In this embodiment, MAC 301 is in FPGA 305. Alternatively, MAC 301 and microprocessor 110 may be in another or third FPGA. Furthermore, MAC 301 and microprocessor 110 may be of a separate microprocessor chip with respect to chips of FPGAs 305 and 306.

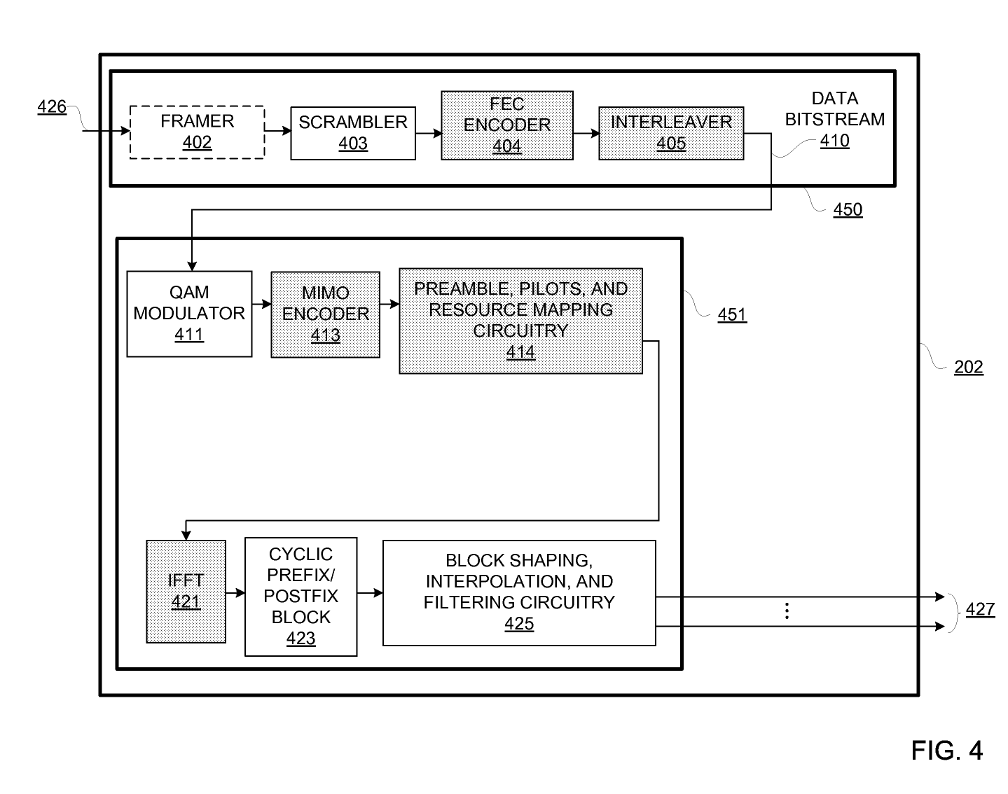

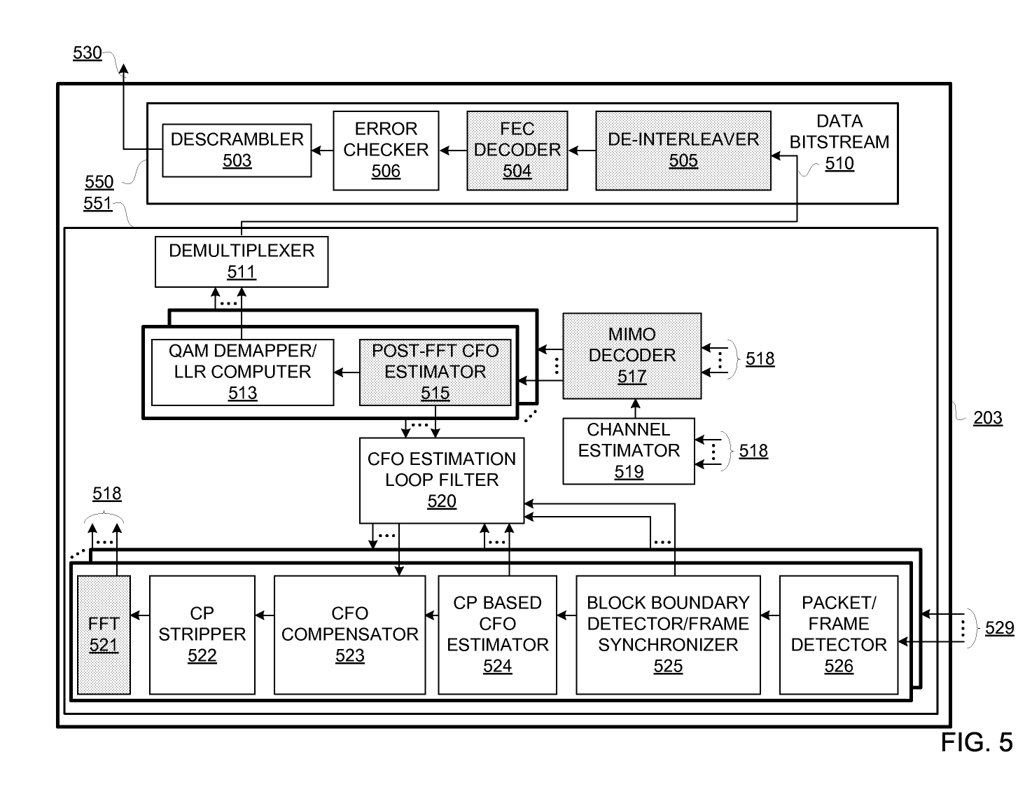

FPGA 305 includes CEM block 202 coupled to a MAC 301 to receive data therefrom, as well as control signaling. FPGA 306 includes CDD block 203 coupled to MAC 301 to provide demodulated and decoded data from CDD block 203 to MAC 301. MAC 301 may be operated using an embedded microprocessor 110 of FPGA 305, or one of the above described alternatives may be used. Alternately, the transmit path may be implemented on multiple FPGAs instead of one FPGA 202. With reference to FIG. 4, the blocks described in FIG. 4 may be partitioned across multiple FPGAs. Similarly, the receive path may be implemented on multiple FPGAs instead of one FPGA 203. With reference to FIG. 5, the blocks described in FIG. 5 may be partitioned across multiple FPGAs.

With reference to FIGS. 2 and 3, it should be appreciated that alternative forms of base stations have been described. Although alternative forms of base stations have been described, it shall be assumed for purposes of clarity and not limitation that base station 200 of FIG. 2 is used in the following description, even though base station 300 may be used. Furthermore, even though examples of base stations are used, it should be appreciated that a subset of the same circuitry used for base stations 200 and 300 may be used for stationary or mobile wireless nodes, including phones, which may be put in communication with base stations 200 and 300. For example, such stationary or mobile wireless nodes may include a single antenna coupled to a transciever or multiple antennas coupled to multiple transeivers. Furthermore, such transceiver of a stationary or mobile wireless node may include blocks 202 and 203 and share a MAC 201.

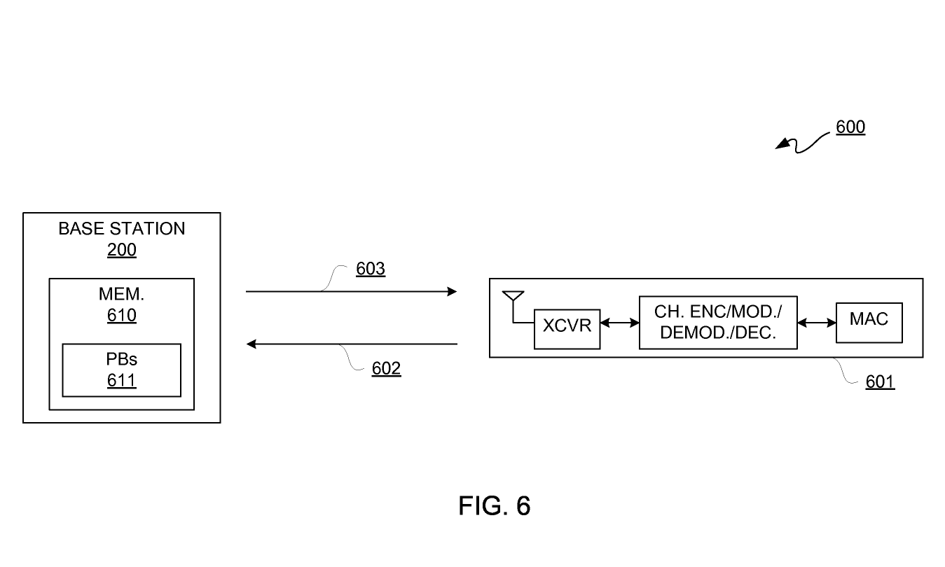

A block diagram depicting an exemplary embodiment of a wireless network 600 is illustratively shown in FIG. 6. Wireless network 600 includes base station 300 and at least one stationary or mobile wireless network node (“subscriber node”) 601. For purposes of clarity by way of example and not limitation, it shall be assumed that subscriber node 601 of FIG. 6 is not configurable by partial reconfiguration as described above. Thus, for purposes of clarity it shall be assumed that network node 601 is conventional, namely includes a conventional transceiver, channel encoder, modulator, demodulator, encoder, and MAC block, among other known components. Accordingly, node/channel conditions signal 602 communicated from network node 601 to base station 200 of FIG. 6 shall be assumed to be a fixed set of parameters.

In a packet mode system, generally a majority of the time is spent in a receive mode waiting for a packet to arrive. In a packet mode system, when a receiver receives a packet and demodulates it, such demodulation is generally followed by a transmitter transmitting an acknowledgment packet back to where the packet was sent from. Thus, after sending an acknowledgement packet back, there is generally sufficient time for reconfiguring a substantial majority, if not all, of the CEM block. Additionally, some portions of a transmitter may be reconfigured, such as an IFFT block. However, in a frame-based system, generally approximately half of the time is spent in a transmitting mode, and approximately the other half of the time is spent in a receiving mode. Thus there may not be sufficient time for reconfiguring a substantial majority of the CEM block. For the CDD block, an FEC decoder and MIMO decoder are blocks that may be targeted for reconfiguration.

FIG. 4 is a block depicting an exemplary embodiment of a CEM block 202 that may be coupled between a MAC and one or more transmitters. Thus, data input may be from MAC 201 for providing I-rail, Q-rail outputs 427 to data converters and RF frontends of one or more of transmitters 210-1 through 210-N of for transmit antennas 211-1 through 211-N of FIGS. 2 and 3.

MAC 201 is coupled to a physical (“PHY”) layer. For purposes of clarity, it shall be assumed that such PHY layer includes at least one, if not both, of CEM block 202 and CDD block 203.

MAC 201 presents information, including data and control signaling 426, to CEM block 202. Data from MAC 201 may be provided to data preparation precursor block 450 of CEM block 202. Optionally, a leading block or subblock of block 450 may be a framer 402, which may precede a scrambler 403. However, as described above, it shall be assumed that packets are used for purposes of clarity and not limitation, and accordingly it shall be assumed that framer 402 is not present.

Data is provided to scrambler 403 for scrambling, and scrambled data from scrambler 403 is provided to forward error correction (“FEC”) encoder block 404. FEC encoder block 404 encodes scrambled data with a selected type of encoding that may be used in a MIMO-OFDM communication system. Output from FEC encoder 404 may be provided to interleaver 405. Output of interleaver 405 may be a data bitstream 410, which is provided to a modulator, such as quadrature amplitude modulation (“QAM”) modulator 411 of MIMO-OFDM modulator block 451.

Modulated data from QAM 411 is provided to MIMO encoder 413 for encoding, and such encoded data is provided to preamble, pilots, and resource mapping circuitry 414 for pre-processing for Inverse Fast Fourier Transform (“IFFT”) block 421. After IFFT block 421 performs an IFFT on a packet, such transformed packet may be provided for a cyclic prefix/postfix insertion by cyclic prefix/postfix insertion block 423. Output of cyclic prefix/postfix block 423 is provided to block shaping, interpolation, and filtering circuitry 425. Output of cyclic prefix/postfix insertion block 423 may be block shaped, interpolated and filtered by circuitry 425 to provide output 427. Output 427 may be input to data converters and then to an analog and RF frontend of a transmitter before providing to a transmit antenna. Output 427 may be for providing to one or more transmitters, as previously described.

FIG. 5 is a block diagram depicting an exemplary embodiment of a CDD block 203 that may be coupled between one or more receivers and a MAC. Information received via one or more of antennas 221-1 through 221-M of FIG. 2 or 3 is provided correspondingly to one or more of receivers 220-1 through 220-M of FIG. 2 or 3. Output from such receivers 220-1 through 220-M is provided to CDD block 203 and, more particularly, to demodulation/decoding block 551. Inputs from receivers 220-1 through 220-M (collectively, “receivers 220”) are provided to CDD block 203 for packet detection and then block boundary detection, as described below in additional detail. Thus, input reception 529 may be from one or more receivers 220 for providing output data 530 to MAC 201 of FIGS. 2 and 3.

Received packets, or frames, from received input 529 from one or more receivers 220 is provided for detection by packet(/frame) detector 526, and output of packet(/frame) detector 526 is provided to block boundary detector(/frame synchronizer) 525. Block boundary detector(/frame synchronizer) 525 identifies the FFT boundaries for the OFDM symbols in the packet or frame and hence is also known as frame synchronization. Block boundary detector(/frame synchronizer) 525 may further identify cyclic prefix and cyclic postfix boundaries. The data with the block boundaries marked is input to the cyclic prefix/postfix (“CP”)-based carrier frequency offset (“CFO”) estimator 524. An output of CP-based CFO estimator 524 is provided as an input to CFO compensator 523. Furthermore, outputs from block boundary detector(/frame synchronizer) 525 and CP-based CFO estimator 524 are provided to CFO estimation loop filter 520. Another input to CFO estimation loop filter 520 is from post-FFT CFO estimator 515.

An output of CP-based CFO estimator 524 is provided to CFO compensator 523, and CFO compensator 523 provides an output to CP stripper 522. CPs are stripped for each of the OFDM symbols by CP stripper 522, and output of CP stripper 522 is provided to FFT block 521. After packet and block boundary are detected, and cyclic prefix and post fix are stripped, then such received and partially processed information is provided to FFT block 521 for transforming the information from the time domain to the frequency domain for further processing.

Packets in the frequency domain are provided from FFT block 521 to channel estimator 519 and MIMO decoder 517. Output of all FFTs are provided to MIMO decoder 517. MIMO decoder 517 decodes packet payload from any and all transmit streams input and provides decoded symbols as previously mapped. MIMO decoder 517 may be partially reconfigured based on a MIMO mode embedded in a “signal” field or “control header”.

Decoded symbols are output from MIMO decoder 517 and provided to post-FFT CFO estimator 515, and output of post-FFT CFO estimator 515 is provided to QAM demapper/log-likelihood-ratio (“LLR”) computer 513, as well as CFO estimation loop filter 520 as previously described. Known functions associated with a receiver, such as log-likelihood ratio functionality and channel estimation functionality, among other known blocks are not described in detail for purposes of clarity and not limitation.

Data and other information from QAM demapper/LLR computer 513 is provided to a demultiplexer 511 if more than one receiver is used. As generally indicated, there may be multiple sets of blocks 521 through 526 for supporting multiple transmit streams. Additionally, there may be multiple sets of blocks 513 and 515 for supporting multiple transmit streams or alternately blocks 513 and 515 may be configured to process multiple streams of information. Data stream 510 output from demultiplexer 511 may be provided to de-interleaver 505 for de-interleaving such data bitstream 510.

A de-interleaved data bitstream output from de-interleaver 505 may be provided to FEC decoder 504. Data post-reception block 550 include FEC decoder 504, which is instantiated at least in part in programmable logic for being subject to partial reconfiguration. FEC decoder 504 decodes such data bitstream to provide decoded data to error checker 506 to check for any errors in transmission of such data. Assuming there are no errors in transmission of such data, or assuming error checker 506 is configured to fix errors in accordance with a decoding mode used, output of error checker 506, namely scrambled data, is provided to descrambler 503. Descrambler 503 is configured to descramble the scrambled data, and output of such unscrambled data or message data 530 is provided to MAC 201.

With simultaneous reference to FIGS. 4 and 5, some blocks in CEM block 202 and CDD block 203 have functions that may be more likely to be dynamically reconfigured using partial reconfiguration responsive to one or more partial bitstreams than other blocks thereof. Such one or more partial bitstreams (“PBs”) 611 may be stored in memory 610 of FIG. 6. Before describing FIGS. 4 and 5 in additional detail, an understanding of how an FPGA may be configured, including partially reconfigured, may be useful.

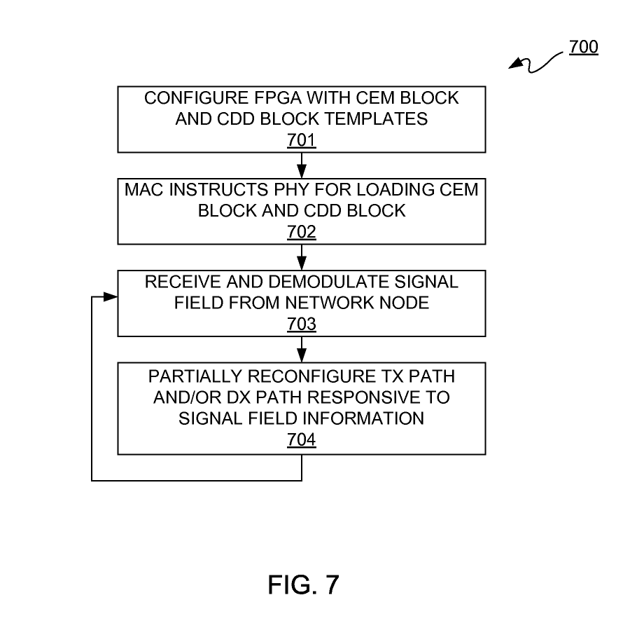

FIG. 7 is a flow diagram depicting an exemplary embodiment of a configuration flow 700. At 701 an integrated circuit such as an FPGA is configured with CEM block and CDD block templates. These block templates may or may not employ default settings for functional blocks of blocks 202 and 203, regarding functional blocks which are more likely subject to partial reconfiguration than other functional blocks. Additionally, use of block templates for configuring an FPGA with CEM and CDD blocks is optional.

Conventionally, base station communication systems have a MAC layer that operates using a microprocessor, such as an embedded processor 110 of FPGA 100 of FIG. 1, as previously described with reference to FIG. 2. Base station communication systems also have a PHY layer which may run using FPGA resources, which may include programmable logic subject to partial reconfiguration.

The MAC layer communicates to one or more higher level layers, such as a networking layer and an application layer. From information provided from one or more higher level layers, the MAC layer, or more generally the microprocessor executing the MAC layer, instructs, such as by issuance of one or more directives or instructions, the PHY layer to reconfigure itself, for example as a transmitter to transmit information.

All or some of CEM block 202 may be loaded into FPGA programmable logic resources, which may be referred to as “FPGA fabric.” For example, a CEM configuration may be loaded into FPGA fabric and provided with data bits for transmitter and packet information. Alternately, only a portion of a CEM configuration may be loaded into FPGA fabric with another portion provided via dedicated or hardwired logic, and all or some of the loaded portion may be subject to being operationally dynamically reconfigured. The transmitter and packet information may be provided from the MAC layer to the PHY layer. Accordingly, a transmit path may be configured and reconfigured responsive to configuration and partial reconfiguration for implementation of the PHY layer to transmit information. The MAC layer, while it is assembling bits to transmit, may trigger a configuration or a partial reconfiguration of programmable logic resources that loads a transmitter into or reconfigures a transmitter of an FPGA.

To receive communicated bits via packets, or frames, and to pass data therefrom from the PHY layer to higher level layers via a receive path, the PHY layer may be initially configured in a basic reception mode. This basic reception mode may be responsive at least in part to information associated with configuration of an associated transmitter, and thus may in effect be provided from one or more higher level layers to the MAC layer for configuration of the receive path of the PHY layer. Thus, when functionality of a transmitter is instantiated, parts of a receiver may be configured or partially reconfigured to receive packets. Furthermore, a basic reception mode may be refined by partial reconfiguration responsive to information received associated with configuration, including partial configuration, of an associated transmitter or information received in transmission while in the basic reception mode, or a combination thereof.

At 702, the MAC layer may instruct the PHY layer for loading CEM and CDD blocks for instantiation of a transmitter and a receiver, respectively. However, this instruction at 702 may be conditioned upon whether configuration of the FPGA is performed with a CEM block template or a CDD block template, or both, at operation 701. For example, if both CEM and CDD block templates are used at 701, then only partial configuration of such CEM and CDD blocks may be used to respectively provide transmit and receive functionality. If operation 701 is used, the MAC layer, which is being executed by microprocessor 110, may instruct the PHY layer to load only those portions of the transmit path or the receive path, or both, which are the subject of partial reconfiguration. If no default settings are specified at 701, loading at 702 may be an initial configuration of configurable or partially configurable function blocks of transmit and receive paths. If operation 701 is not used, then the MAC layer may instruct the loading of what amounts to transmit and receive paths at 702, namely loading of all portions of CEM and CDD blocks to be instantiated in FPGA fabric, including any initial settings thereof.

Communication systems may employ what is known as a “signal” field, namely some form of control header or preamble, that instructs or informs a receiver as to the kind of option or mode with which the transmitter has encoded a packet. This signal field provides information on the Fast Fourier Transform (“FFT”) point size to use and the MIMO decoding type to use. This signal field is usually modulated using a basic mode initially, and once the signal field is demodulated using this basic or default demodulator configuration, such as may be instantiated at 701 or 702 for example, information from such signal field may be used to trigger a partial reconfiguration of an FPGA to effectively load various capabilities, such as for example an FFT point size to use for an OFDM demodulator and an appropriate decoding type for a MIMO decoder. In other words, the MAC layer, or more generally the microprocessor executing the MAC layer, may issue one or more directives for configuration or partial reconfiguration responsive to receipt, or more particularly demodulation, of control information, such as signal field for example, received in a wireless transmission. Alternatively or in combination with control information obtained from such a wireless transmission, all or some of such control information for a network node may be obtained when such network node is deployed. For example, different countries have different bandwidth requirements and therefore some of the options of a communication system may be different from country to country. Accordingly, when such a communication system is “powered up,” a default configuration can be loaded, such as via a hardwired connection or an over-the-air communication to such network node for configuration at least in part in programmable logic of one or more country specific options, which later may be reconfigured. However, for purposes of clarity by way of example and not limitation, it shall be assumed that a default configuration has been initially loaded.

The signal field may further have information about the type of decoder and the rate of the channel code. Accordingly, once the signal field is demodulated using a basic demodulator configuration, information obtained from such signal field may be used to trigger partial reconfiguration to load the type of FEC to be used for channel decoding. The rate of the channel code may be varied to minimize overhead and increase user data throughput.

CEM and CDD blocks instantiated as templates at 701 and refined at 702 for example may thus be configured to demodulate a signal field which is received and demodulated at 703. Such signal field may be from network node 601 of FIG. 6 provided via a node/channel conditions signal 602.

At 704, responsive to signal field information demodulated at 703, one or both of a transmission (“TX”) path and a data (“DX”) path may be partially reconfigured. For example, information obtained from a signal field or some “control” preamble may be the FFT point size. As described below in additional detail, the point size for an FFT block of a receiver and an IFFT block of a transmitter may be specified using information from a signal field. Additionally, the number of antennas to be used with a MIMO transmitter and a MIMO receiver, which may depend upon the MIMO mode and the number of such antennas available, may be determined from a signal field. Furthermore, the type of MIMO encoding for a symbol encoder, and correspondingly decoding for symbol decoder may be specified using information from a signal field. Moreover, from signal field information obtained at 703, the type of FEC encoding, and correspondingly the type of FEC decoding, may be determined for an FEC encoder block and an FEC decoder block, respectively.

Additionally, the rate and type at which this encoding or decoding is done, namely the rate and type of the channel code indicated in a signal field, has an effect on overhead. For example, a turbo encoder uses more resources than a convolutional encoder of identical rate. The rate and type of the channel code may be obtained from signal field information obtained at 703 in order to scale the size of an FEC decoder block and an FEC encoder block to accommodate such rate of channel code. Once an FPGA has been initially configured with CEM and CDD blocks for example, it may be dynamically reconfigured responsive to another signal field, such as may be received from a different stationary or wireless node. Furthermore, it should be appreciated that various locales may have different transmitter bandwidths specified, and thus the ability to provide a transmitter platform that may be configured or dynamically reconfigured to accommodate various transmitter bandwidths may be useful. For purposes of clarity by way of example and not limitation, it shall be assumed that such dynamic reconfiguration is a dynamic partial reconfiguration of one or more functional blocks of one or both of CEM and CDD blocks for being completed while one or more of such blocks are not in use.

With simultaneous reference to the block diagram of FIG. 6, which depicts an exemplary embodiment of a wireless network 600, FIGS. 4 and 5 are further described. For purposes of clarity by way of example and not limitation, FEC encoder 404 and interleaver 405 of data preparation precursor blocks 450, and MIMO encoder 413, IFFT block 421, and circuitry 414 of MIMO-OFDM modulator block 451 are described as each being potentially subject to being instantiated in whole or in part in programmable logic of an FPGA, such as programmable device 206 of FIG. 2, and reconfigured subject to partial reconfiguration, which may or may not be dynamically loaded. Likewise, FEC decoder 504 and de-interleaver of data post-reception blocks 550, and post-FFT CFO estimator 515, MIMO decoder 517, and FFT block 521 of MIMO-OFDM demodulator block 551 are described as each being potentially subject to being instantiated in whole or in part in programmable logic of an FPGA, such as programmable device 206 of FIG. 2, and reconfigured subject to partial reconfiguration, which may or may not be dynamically loaded.

The type of FEC encoding to be used may be determined responsive to information in node/channel conditions signal 602 obtained from node 601. FEC encoder block 404 may be implemented in one or more layers, and may be partially reconfigured, or initially configured for any of a variety of known types of FEC encodings. Example types of encodings that may be used in a MIMO-OFDM communication system include Reed-Solomon/Viterbi encoding, CTC encoding, LDPC encoding, and TPC encoding. Accordingly, there may be separate partial bitstreams respectively associated with Reed-Solomon/Viterbi encoding, CTC encoding, LDPC encoding, and TPC encoding for instantiation of one of these types of encoding functions as FEC encoding block 404 in programmable logic using partial reconfiguration. Such partial bitstreams, namely partial bitstreams 611, may be stored in memory 610 for on demand access by an FPGA. Memory 610 may be any of a variety of known types of memory, including solid state memory located on a circuit board.

Output from FEC encoder block 404, namely FEC encoded scrambled data, is provided to interleaver 405. Interleaver 405 may include one or more levels of interleaving which may be initially configured or partially reconfigured for any of a variety of known levels. Output of interleaver 405 is a data bitstream 410.

Because a base station may communicate with multiple subscribers or multiple subscriber stations, MAC 201 may provide information to different users, whether point-to-point, broadcast, or other known communication format. Accordingly, multiple users may be mapped to appropriate channels or sub-carriers, as is known. Parameters, which may be set via control registers (not shown) associated with MAC 201, may for example include the number of sub-carriers, the number of antennas, or the packet structure, among other known parameters for a base station and also for individual subscriber units. Parameters associated with a packet structure which may be set via control registers for example may include one or more of the number of training symbols, the type of preamble, pilot locations, or cyclic prefix/postfix. Parameters associated with the frame may be the mapping of sub-carriers to specific users, and the pilots may be associated with specific user mappings. Parameter settings, as well as circuitry instantiated as associated with such parameter settings, may be initially configured or partially reconfigured to provide circuitry 414.

Data bitstream 410 is provided as an input to QAM modulator 411. QAM modulator 411 is part of MIMO-OFDM modulator block 451 of CEM block 202. Accordingly, there may be respective partial bitstreams associated with IFFT point sizes. For this example, there may be six separate partial bitstreams respectively associated with point sizes of 64, 128, 256, 512, 1024, or 2048 for instantiation of IFFT block 421 in programmable logic of programmable device 206 for a selected point size, which may be initially configured or partially reconfigured.

Output from QAM modulator 411, namely mapped symbols, is provided to MIMO encoder 413 for MIMO encoding or spatial encoding block. Examples of symbol encoding modes for use in a MIMO-OFDM communication system may include STBC encoding or spatial multiplexing, which may be initially configured or partially reconfigured in FPGA fabric.

Encoded symbols output from MIMO encoder 413 are input to circuitry 414, such as for pilot insertion where pilots and data for a particular user are mapped to particular subcarriers. Pilot insertion inserts pilot information symbols, namely information about the transmitting system, into predefined sub-carrier locations. These inserted pilot symbols are known by receivers in communication with a transmitter system, as they are predefined. Additionally, one or more symbols may be stored for detection of a predefined preamble, which may be initially configured or partially reconfigured in FPGA fabric.

Packets output from circuitry 414 are provided as input to IFFT block 421. Point size for an IFFT may be selected from among a variety of sizes. Examples of such sizes are 64, 128, 256, 512, 1024, 2048, and so on. The IFFT point size may be information communicated via node/channel conditions signal 602 to base station 300. Furthermore, when taking into account the number of IFFT point sizes supported, where each IFFT-supported point size may be instantiated using one or more IFFT circuits there may be respective partial bitstreams for each supported combination of IFFT point size.

It should be appreciated that the remainder of an FPGA may continue to operate even though circuitry instantiated in programmable logic associated with CEM block 202 undergoes partial reconfiguration. For example, operation of CEM block 202 may be stalled while CDD block 203 continues to process received data.

Demodulation/decoding block 551 includes blocks 511, 513, 515, 517, and 519 through 526. Data post-reception block 550 includes blocks 503 through 506. Of these two sets of blocks, one or more of blocks 504, 505, 515, 517, and 521 may each be potentially configured at least in part using programmable logic resources that may be reconfigured responsive to partial reconfiguration. This partial reconfiguration may or may not be done dynamically.

It should be appreciated that FEC encoder 404, interleaver 405, MIMO encoder 413, and IFFT block 421 of a transmit path of CEM block 202 of FIG. 4 respectively with inverse functionality correspond to FEC decoder 504, de-interleaver 505, MIMO decoder 517, and FFT block 521 of a receive path of CDD block 203 of FIG. 5. Furthermore, generally MIMO decoder 517 is an inverse operation MIMO encoding by MIMO encoder 413. In other words, if for example one type of encoding is used, than the corresponding type of decoding is used, and thus the selection of a partial bitstream for encoding predicts selection of a partial bitstream for decoding. Thus, CDD block 203 may be partially reconfigured responsive to partial reconfiguration of an associated CEM block 202. Responsive to signal field information such as may be obtained from node/channel conditions signal 602 of FIG. 6, one or more partial bitstreams of partial bitstreams 611 may be obtained from memory 610 for partial reconfiguration of CDD block 203, including one or more partially reconfigurable blocks thereof as described herein. Accordingly, it should be appreciated that the number of FPGAs, as well as the size and complexity of an associated circuit board and chipset thereof, may be reduced by using partial reconfiguration as described herein for a MIMO-OFDM communication system.

While the foregoing describes exemplary embodiment(s) in accordance with one or more aspects of the invention, other and further embodiment(s) in accordance with the one or more aspects of the invention may be devised without departing from the scope thereof, which is determined by the claim(s) that follow and equivalents thereof. Claim(s) listing steps do not imply any order of the steps. Trademarks are the property of their respective owners.

What is claimed is:

1. A method for providing a communication system, comprising:
instantiating a physical layer block in a programmable device;
the physical layer block instantiated at least in part in programmable logic of the programmable device;
obtaining communication information from a first wireless network node of a communication network to configure a portion of the physical layer block of a second wireless network node of the communication network using the programmable logic;
the communication system being part of the second wireless network node of the communication network;
configuring the portion of the physical layer block responsive to the communication information;
the configuring of the portion of the physical layer block including:
selectively obtaining at least one partial bitstream from a store of partial bitstreams responsive to the communication information;
the communication information being associated with the communication network in which the communication system is capable of being deployed; and
loading the at least one partial bitstream into the programmable logic for the configuring of the portion of the physical layer block.

2. The method according to claim 1, wherein:
the configuring of the portion of the physical layer block is a dynamic partial reconfiguration of a transmitter; and
the communication information includes signal field information.

3. The method according to claim 1, wherein the physical layer block is a channel encoding/modulation block associated with a transmit path of the communication system.

4. The method according to claim 3, wherein the portion of the physical layer block includes a forward-error-correction encoder and an interleaver.

5. The method according to claim 3, wherein the portion of the physical layer block includes a preamble, pilots, and resource mapping block.

6. The method according to claim 3, wherein the portion of the physical layer block includes a Multiple-input, Multiple-Output encoder.

7. The method according to claim 3, wherein the portion of the physical layer block includes an Inverse Fast Fourier Transform block.

8. The method according to claim 1, wherein the physical layer block is a channel decoding/demodulation block associated with a receive path of the communication system.

9. The method according to claim 8, wherein the portion of the physical layer block includes a forward-error-correction decoder and a de-interleaver.

10. The method according to claim 8, wherein the portion of the physical layer block includes a post-Fast Fourier Transform Carrier Frequency Offset estimator.

11. The method according to claim 8, wherein the portion of the physical layer block includes a Multiple-input, Multiple-Output decoder.

12. The method according to claim 8, wherein the portion of the physical layer block includes a Fast Fourier Transform block.

13. A method for providing a communication system, comprising:
configuring at least a portion of a physical layer block in a programmable device responsive to at least one directive from a microprocessor that is executing a media access control layer of the communication system;
while the microprocessor executes the media access control layer, the configuring including:
obtaining a communication from a wireless transmission from a network node of a communication network;
the communication having control information;
the control information being associated with the communication network in which the communication system is capable of being deployed;
the obtaining of the control information prompting the microprocessor to issue the at least one directive;
selecting using the microprocessor at least one partial bitstream from a store of partial bitstreams responsive to the control information obtained;
decoding the control information in the physical layer block to output decoded information;
sending the decoded information to the media access control layer being executed using the microprocessor; and
loading the at least one partial reconfiguration bitstream into the programmable logic for the configuring of at least the portion of the physical layer block responsive to the at least one directive from the microprocessor.

13. The method according to claim 12, wherein the configuring of the portion of the physical layer block is a dynamic partial reconfiguration of a transmitter.

14. The method according to claim 12, wherein the portion of the physical layer block includes a channel encoding/modulation block associated with a transmit path of the communication system.

15. The method according to claim 14, wherein the portion of the physical layer block further includes a channel decoding/demodulation block associated with a receive path of the communication system.

16. The method according to claim 15, wherein:
the channel encoding/modulation block of the portion of the physical layer block includes a Multiple-input, Multiple-Output encoder; and
the channel decoding/demodulation block of the portion of the physical layer block includes a Multiple-input, Multiple-Output decoder.

17. The method according to claim 15, wherein:
the channel encoding/modulation block of the portion of the physical layer block includes a forward-error-correction encoder and an interleaver; and
the channel decoding/demodulation block of the portion of the physical layer block includes a forward-error-correction decoder and a de-interleaver.

18. The method according to claim 15, wherein:
the channel encoding/modulation block of the portion of the physical layer block includes an Inverse Fast Fourier Transform block; and
the channel decoding/demodulation block of the portion of the physical layer block includes a Fast Fourier Transform block.

19. A communication system, comprising:
a physical layer block instantiated in a programmable device;
the first physical layer block capable of being instantiated in part in programmable logic of the programmable device for dynamic partial reconfiguration of a portion of the physical layer block;
bitstream information selectively retrievable from a store of partial bitstreams for the dynamic partial reconfiguration of the portion of the physical layer block; and
the bitstream information capable of being selectively retrieved responsive to control information obtained from a transmission for a communication network in which the communication system associated with the physical block layer is capable of being deployed.

20. The communication system according to claim 14, wherein:
the transmission is a wireless transmission;
the control information is a signal field;
the communication system is part of one of a subscriber node or a base station of the communication network; and
the communication system is a Multiple-input, Multiple-Output Orthogonal Frequency Division Multiplexing (“Multiple-input, Multiple-Output-OFDM”) communication system.
